(19) United States
(12) Patent Application Publication
(10) Pub. No.: US 2025/0324827 A1
(43) Pub. Date: Oct. 16, 2025

(54) WAVELENGTH CONVERTER WITH STEPPED-INDEX ANTI-REFLECTION LAYERS

(71) Applicant: Lumileds LLC, San Jose, CA (US)

(72) Inventors: Florent MONESTIER, Kerkrade (NL); Yu-Chen Shen, Sunnyvale, CA (US); Marcel Rene Bohmer, Eindhoven (NL)

(73) Assignee: Lumileds LLC, San Jose, CA (US)

(21) Appl. No.: 19/249,576

(22) Filed: Jun. 25, 2025

Related U.S. Application Data
(63) Continuation of application No. PCT/US2024/011160, filed on Jan. 11, 2024.
(60) Provisional application No. 63/439,070, filed on Jan. 13, 2023.

(51) Int. Cl. H10H 20/851; H10H 20/01; H10H 20/82; H10H 29/01; H10H 29/14

(52) U.S. Cl. CPC H10H 20/8514; H10H 20/0361; H10H 20/82; H10H 29/0361; H10H 29/142

(57) ABSTRACT

A light-emitting apparatus includes a luminescent structure and a stepped-index structure, and can further include an LED. The luminescent structure absorbs light at an excitation wavelength and emits light at one or more emission wavelengths longer than the excitation wavelength. The stepped-index structure is a stack of multiple transparent layers positioned between and in contact with an ambient medium and the luminescent structure, with corresponding refractive indices lower than the refractive index of the luminescent structure, higher than the refractive index of the ambient medium, and monotonically decreasing from the luminescent structure toward the ambient medium. The LED can be positioned with its light-emitting surface facing the surface of the luminescent structure opposite the stepped-index structure. The stepped-index structure can increase transmission of light from the luminescent structure into the ambient medium.

### PRIORITY CLAIM

This application is a continuation of international App. No. PCT/US2024/011160entitled “Wavelength converter with stepped-index anti-reflection layers” filed 11 Jan. 2024 in the names of Monestier et al, which claims priority of U.S. provisional App. No. 63/439,070 entitled “Wavelength converter with stepped-index anti-reflection layers” filed 13 Jan. 2023 in the names of Monestier et al, both of said applications being incorporated herein by reference in their entireties.

### FIELD OF THE INVENTION

The invention relates generally to light emitting diodes and to phosphor-converted light emitting diodes.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths. In a light-emitting device where the light emitted by the semiconductor LED is the only output, that device can be referred to as a direct-emitting LED, or simply as an LED (although “LED” can sometimes refer collectively to both direct-emitting LEDs and the phosphor-converted LEDs described next).

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer.

Phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED.

Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Multiple LEDs or pcLEDs can be formed together on a single substrate to form an array. Such arrays can be employed to form active illuminated displays, such as those employed in, e.g., smartphones and smart watches, computer or video displays, augmented-or virtual-reality displays, or signage, or to form adaptive illumination sources, such as those employed in, e.g., automotive headlights, street lighting, camera flash sources, or flashlights (i.e., torches). An array having one or several or many individual devices per millimeter (e.g., nonzero device pitch or spacing of about a millimeter, a few hundred microns, or less than 100 microns, and nonzero separation between adjacent devices less than 100 microns or only a few tens of microns or less) typically is referred to as a miniLED array or a microLED array (alternatively, a μLED array). Such mini-or microLED arrays can in many instances also include phosphor converters as described above; such arrays can be referred to as pc-miniLED or pc-microLED arrays.

### SUMMARY

An inventive light-emitting apparatus includes a luminescent structure and a stepped-index structure, and can further include an LED. The luminescent structure comprises one or more luminescent materials that absorb light at an excitation wavelength and, as a result of that absorption, emit light at one or more emission wavelengths that are longer than the excitation wavelength. The luminescent structure has opposite first and second surfaces thereof. The stepped-index structure comprises a stack of multiple transparent layers, each characterized by a corresponding effective refractive index that is lower than an effective refractive index of the first surface of the luminescent structure and higher than a refractive index of an ambient medium. The stepped-index structure is positioned between and in contact with the ambient medium and the first surface of the luminescent structure. The corresponding effective refractive indices of the transparent layers decrease monotonically among the transparent layers with increasing distance of each transparent layer from the first surface of the luminescent structure. The LED can be positioned with its light-emitting surface facing the second surface of the luminescent structure. The stepped-index structure can increase transmission of light from the luminescent structure into the ambient medium.

Objects and advantages pertaining to LEDs, pcLEDs, miniLED arrays, pc-miniLED arrays, microLED arrays, and pc-microLED arrays may become apparent upon referring to the examples illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a schematic cross-sectional view of an example pcLED.

FIGS. 2A and 2B show, respectively, cross-sectional and top schematic views of an example array of pcLEDs.

FIG. 3A shows a schematic cross-sectional view of an example array of pcLEDs arranged with respect to waveguides and a projection lens. FIG. 3B shows an arrangement similar to that of FIG. 3A, but without the waveguides.

FIG. 4A shows a top schematic view of an example miniLED or microLED array and an enlarged section of 3×3 LEDs of the array. FIG. 4B is a side cross-sectional schematic diagram of an example of a close-packed array of multi-colored phosphor-converted LEDS on a monolithic die and substrate.

FIG. 5A is a schematic top view of a portion of an example LED display in which each display pixel is a red, green, or blue phosphor-converted LED pixel. FIG. 5B is a schematic top view of a portion of an example LED display in which each display pixel includes multiple phosphor-converted LED pixels (red, green, and blue) integrated onto a single die that is bonded to a control circuit backplane.

FIG. 6A shows a schematic top view an example electronics board on which an array of pcLEDs may be mounted, and FIG. 6B similarly shows an example array of pcLEDs mounted on the electronic board of FIG. 6A.

FIG. 7A schematically illustrates an example camera flash system. FIG. 7B schematically illustrates an example display system. FIG. 7C shows a block diagram of an example visualization system.

FIGS. 8A and 8B are schematic side cross-sectional views of examples of an inventive light-emitting apparatus with a stepped-index structure.

FIGS. 9A-9C are schematic side cross-sectional views of examples of an inventive light-emitting apparatus with a stepped-index structure.

The examples depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. For example, individual LEDs may be exaggerated in their vertical dimensions or layer thicknesses relative to their lateral extent or relative to substrate or phosphor thicknesses. The examples shown should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the inventive subject matter. The detailed description illustrates by way of example, not by way of limitation, the principles of the inventive subject matter. For purposes of simplicity and clarity, detailed descriptions of well-known devices, circuits, and methods may be omitted so as not to obscure the description of the inventive subject matter with unnecessary detail.

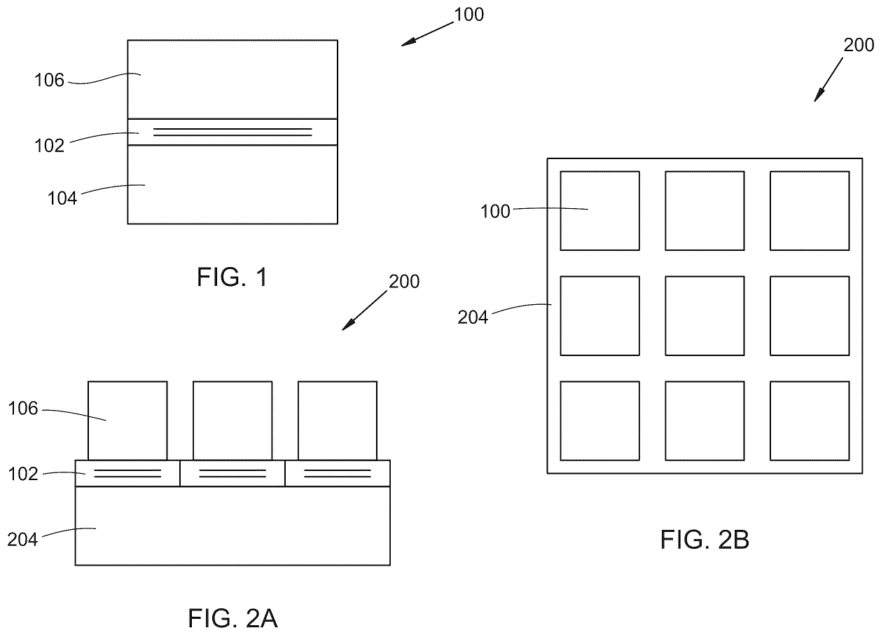

FIG. 1 shows an example of an individual pcLED 100 comprising a semiconductor diode structure 102 disposed on a substrate 104, together considered herein an “LED” or “semiconductor LED”, and a wavelength converting structure (e.g., phosphor layer) 106 disposed on the semiconductor LED. Semiconductor diode structure 102 typically comprises an active region disposed between n-type and p-type layers. Application of a suitable forward bias across the diode structure 102 results in emission of light from the active region. The wavelength of the emitted light is determined by the composition and structure of the active region.

The LED may be, for example, a III-Nitride LED that emits blue, violet, or ultraviolet light. LEDs formed from any other suitable material system and that emit any other suitable wavelength of light may also be used. Other suitable material systems may include, for example, III-Phosphide materials, III-Arsenide materials, other binary, ternary, or quaternary alloys of gallium, aluminum, indium, nitrogen, phosphorus, or arsenic, or II-VI materials.

Any suitable phosphor materials may be used for or incorporated into the wavelength converting structure 106, depending on the desired optical output from the pcLED.

FIGS. 2A-2B show, respectively, cross-sectional and top views of an array 200 of pcLEDs 100, each including a phosphor pixel 106, disposed on a substrate 204. Such an array can include any suitable number of pcLEDs arranged in any suitable manner. In the illustrated example the array is depicted as formed monolithically on a shared substrate, but alternatively an array of pcLEDs can be formed from separate individual pcLEDs (e.g., singulated devices that are assembled onto an array substrate). Individual phosphor pixels 106 are shown in the illustrated example, but alternatively a contiguous layer of phosphor material can be disposed across multiple LEDs 102. In some instances the array 200 can include light barriers (e.g., reflective, scattering, and/or absorbing) between adjacent LEDs 102, phosphor pixels 106, or both. Substrate 204 may optionally include electrical traces or interconnects, or CMOS or other circuitry for driving the LED, and may be formed from any suitable materials.

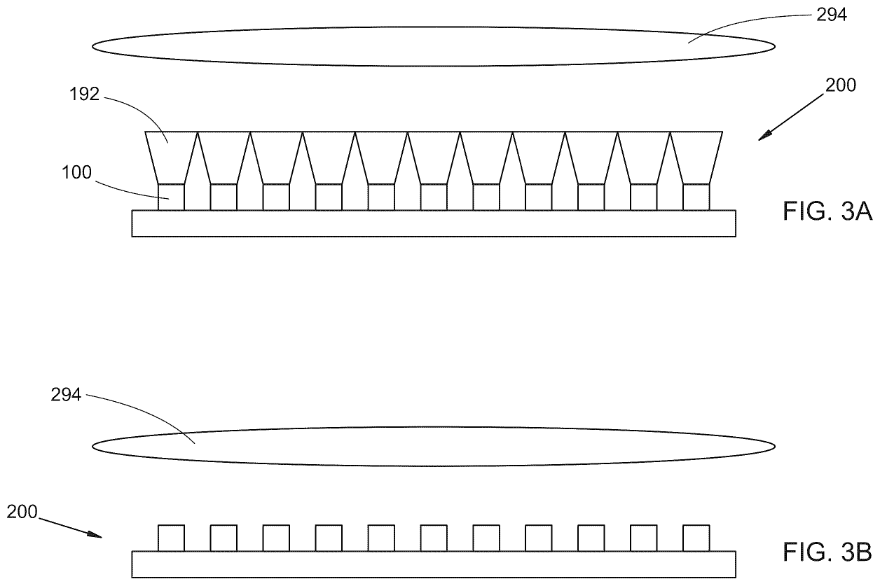

Individual pcLEDs 100 may optionally incorporate or be arranged in combination with a lens or other optical element located adjacent to or disposed on the phosphor layer (if present) or on a surface of direct-emitting LED(s). Such an optical element may be referred to as a “primary optical element”. In addition, as shown in FIGS. 3A and 3B, a pcLED array 200 (for example, mounted on an electronics board) may be arranged in combination with secondary optical elements such as waveguides, lenses, or both for use in an intended application. In FIG. 3A, light emitted by each pcLED 100 of the array 200 is collected by a corresponding waveguide 192 and directed to a projection lens 294. Projection lens 294 may be a Fresnel lens, for example. This arrangement may be suitable for use, for example, in automobile headlights or other adaptive illumination sources. Other primary or secondary optical elements of any suitable type or arrangement can be included for each pixel, as needed or desired. In FIG. 3B, light emitted by pcLEDs of the array 200 is collected directly by projection lens 294 without use of intervening waveguides. This arrangement may particularly be suitable when pcLEDs can be spaced sufficiently close to each other, and may also be used in automobile headlights as well as in camera flash applications or other illumination sources. A miniLED or microLED display application may use similar optical arrangements to those depicted in FIGS. 3A and 3B, for example. Generally, any suitable arrangement of optical elements (primary, secondary, or both) can be used in combination with the pcLEDs described herein, depending on the desired application.

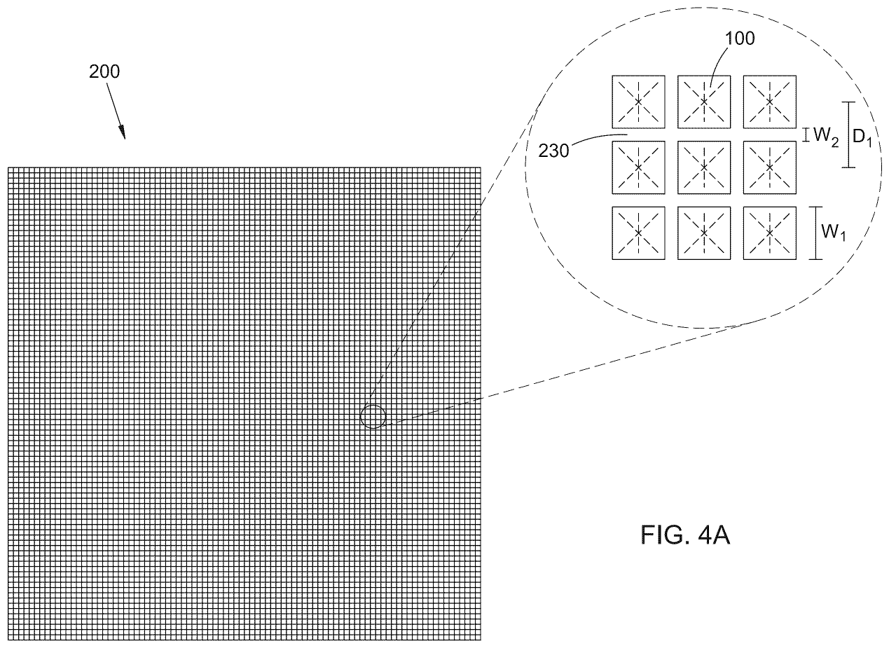

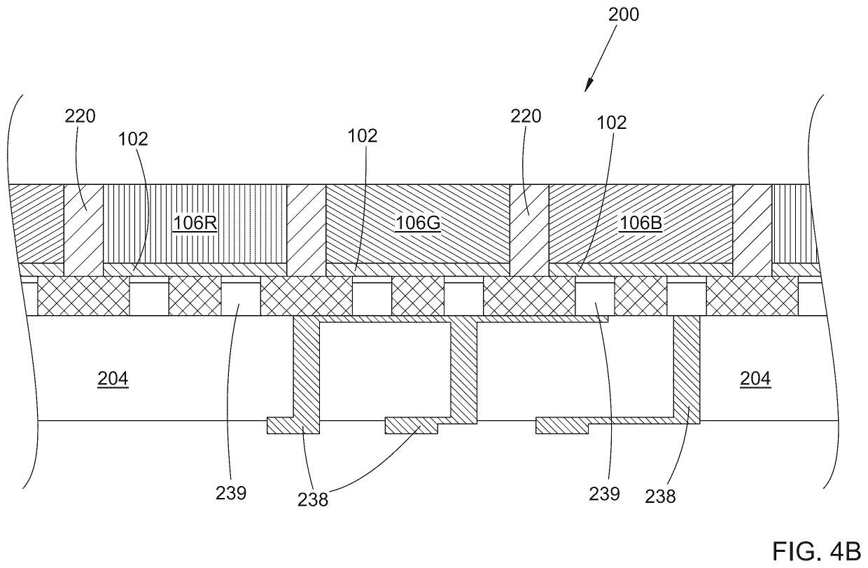

Although FIGS. 2A and 2B show a 3×3 array of nine pcLEDs, such arrays may include for example on the order of 101, 102, 103, 104, or more LEDs, e.g., as illustrated schematically in FIG. 4A. Individual LEDs 100 (i.e., pixels) may have nonzero widths w₁ (e.g., side lengths) in the plane of the array 200, for example, less than or equal to 1 millimeter (mm), less than or equal to 500 microns, less than or equal to 100 microns, or less than or equal to 50 microns (“nonzero” width meaning that however small the width of the LED, it still can function as an LED). LEDs 100 in the array 200 may be spaced apart from each other by streets, lanes, or trenches 230 having a nonzero width w₂ in the plane of the array 200 of, for example, hundreds of microns, less than or equal to 100 microns, less than or equal to 50 microns, less than or equal to 20 microns, less than or equal to 10 microns, or less than or equal to 5 microns (“nonzero” meaning that however small the width of the trench, it still separates adjacent LEDs so that they can operate independently). The pixel pitch or spacing Di is the sum of w₁ and w₂. Although the illustrated examples show rectangular pixels arranged in a symmetric matrix, the pixels and the array may have any suitable shape or arrangement, whether symmetric or asymmetric. Multiple separate arrays of LEDs can be combined in any suitable arrangement in any applicable format to form a larger combined array or display.

LEDs having nonzero dimensions w₁ in the plane of the array (e.g., side lengths) of less than or equal to about 0.10 millimeters microns are typically referred to as microLEDs, and an array of such microLEDs may be referred to as a microLED array. LEDs having dimensions w₁ in the plane of the array (e.g., side lengths) of between about 0.10 millimeters and about 1.0 millimeters are typically referred to as miniLEDs, and an array of such miniLEDs may be referred to as a miniLED array.

FIG. 4B is a schematic cross-sectional view of a close packed array 200 of multi-colored, phosphor converted LEDs 100 on a monolithic die and substrate 204. The side view shows GaN LEDs 102 attached to the substrate 204 through metal interconnects 239 (e.g., gold-gold interconnects or solder attached to copper micropillars) and metal interconnects 238. Phosphor pixels 106 are positioned on or over corresponding GaN LED pixels 102. The semiconductor LED pixels 102 or phosphor pixels 106 (often both) can be coated on their sides with a reflective mirror or diffusive scattering layer to form an optical isolation barrier 220. In this example each phosphor pixel 106 is one of three different colors, e.g., red phosphor pixels 106R, green phosphor pixels 106G, and blue phosphor pixels 106B (still referred to generally or collectively as phosphor pixels 106). Such an arrangement can enable use of the LED array 200 as a color display.

The individual LEDs (pixels) in an LED array may be individually addressable, may be addressable as part of a group or subset of the pixels in the array, or may not be addressable. Thus, light emitting pixel arrays are useful for any application requiring or benefiting from fine-grained intensity, spatial, and temporal control of light distribution. These applications may include, but are not limited to, precise special patterning of emitted light from pixel blocks or individual pixels, in some instances including the formation of images as a display device. Depending on the application, emitted light may be spectrally distinct, adaptive over time, and/or environmentally responsive. The light emitting pixel arrays may provide preprogrammed light distribution in various intensity, spatial, or temporal patterns. The emitted light may be based at least in part on received sensor data and may be used for optical wireless communications. Associated electronics and optics may be distinct at a pixel, pixel block, or device level.

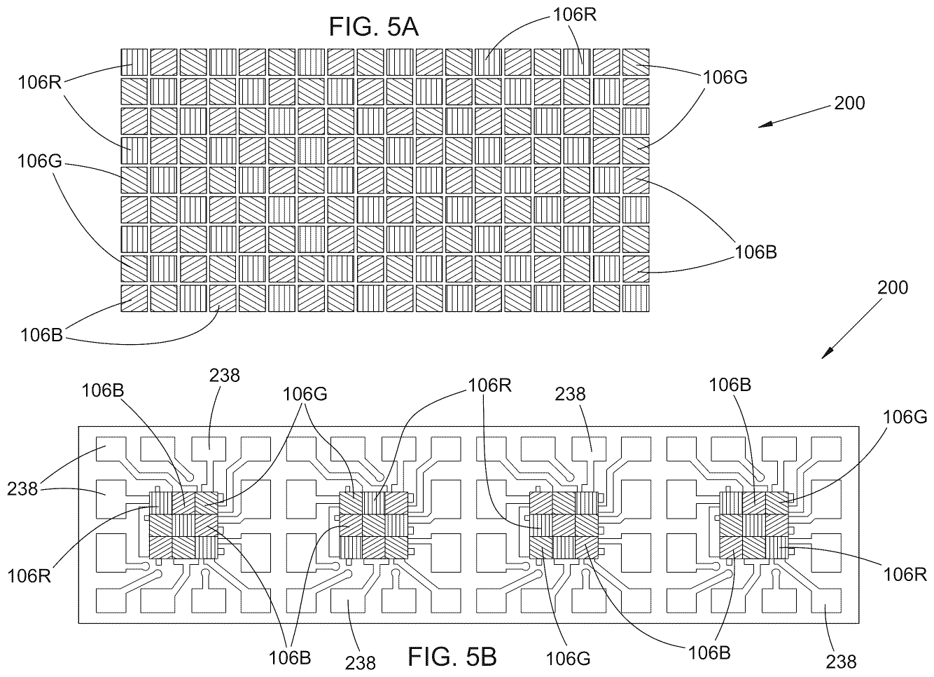

FIGS. 5A and 5B are examples of LED arrays 200 employed in display applications, wherein an LED display includes a multitude of display pixels. In some examples (e.g., as in FIG. 5A), each display pixel comprises a single semiconductor LED pixel 102 and a corresponding phosphor pixel 106R, 106G, or 106B of a single color (red, green, or blue). Each display pixel only provides one of the three colors. In some examples (e.g., as in FIG. 5B), each display pixel includes multiple semiconductor LED pixels 102 and multiple corresponding phosphor pixels 106 of multiple colors. In the example shown each display pixel includes a 3×3 array of semiconductor pixels 102; three of those LED pixels have red phosphor pixels 106R, three have green phosphor pixels 106G, and three have blue phosphor pixels 106B. Each display pixel can therefore produce any desired color combination. In the example shown the spatial arrangement of the different colored phosphor pixels 106 differs among the display pixels; in some examples (not shown) each display pixel can have the same arrangement of the different colored phosphor pixels 106.

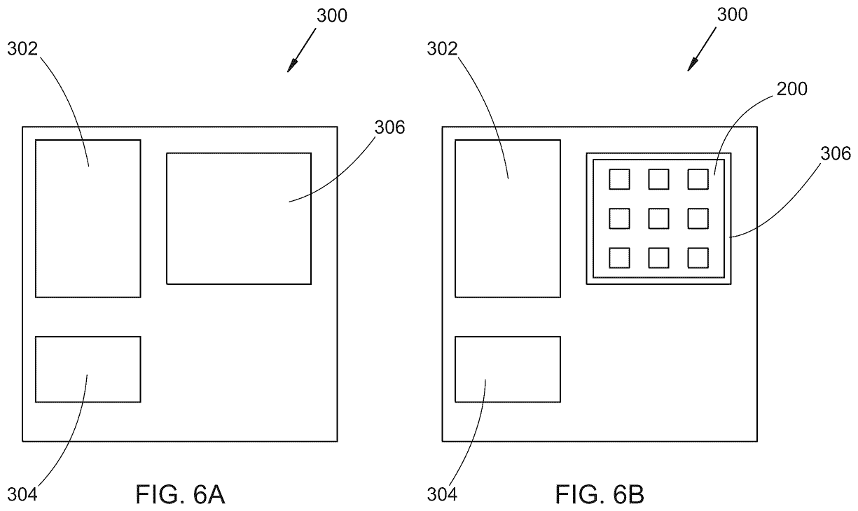

As shown in FIGS. 6A and 6B, a pcLED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, pcLED array 200 may be mounted on a separate board (not shown) from the power and control module and the sensor module.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g., adaptive headlights), mobile device camera (e.g., adaptive flash), AR, VR, and MR applications such as those described below.

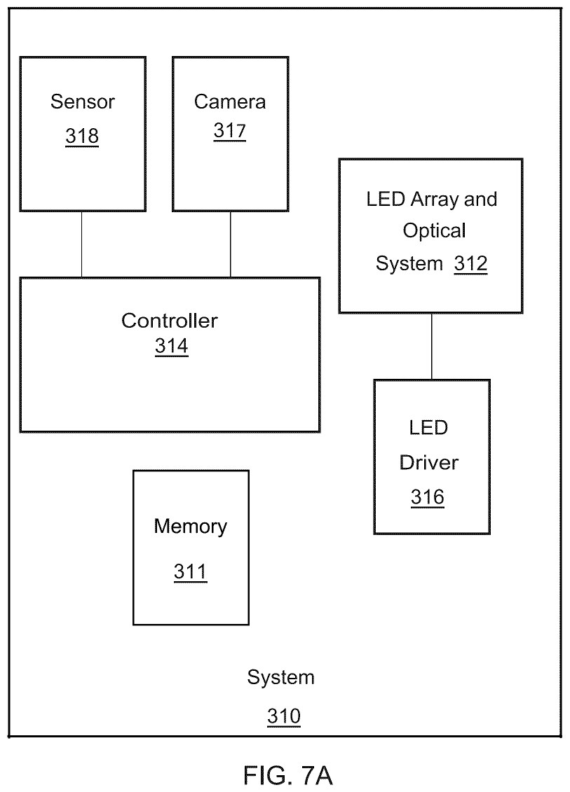

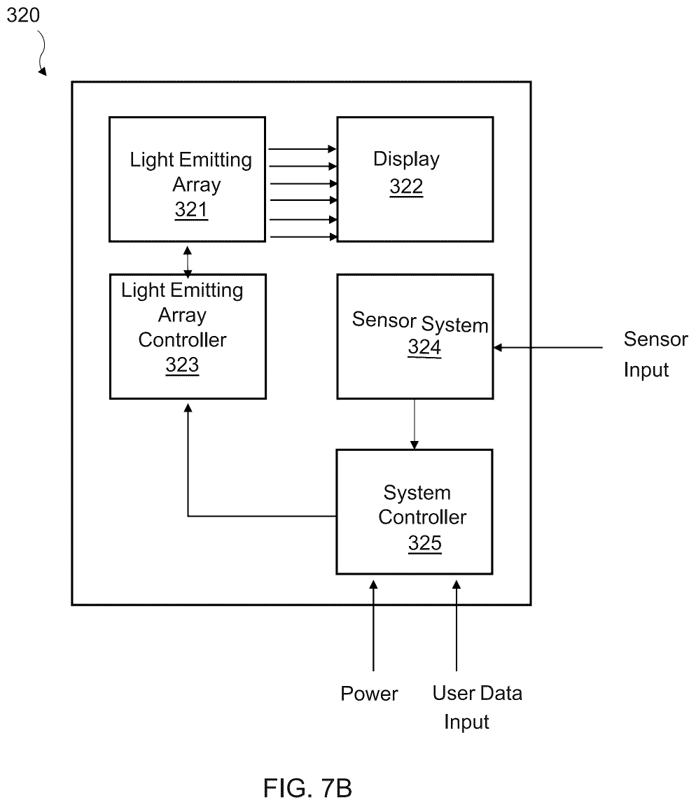

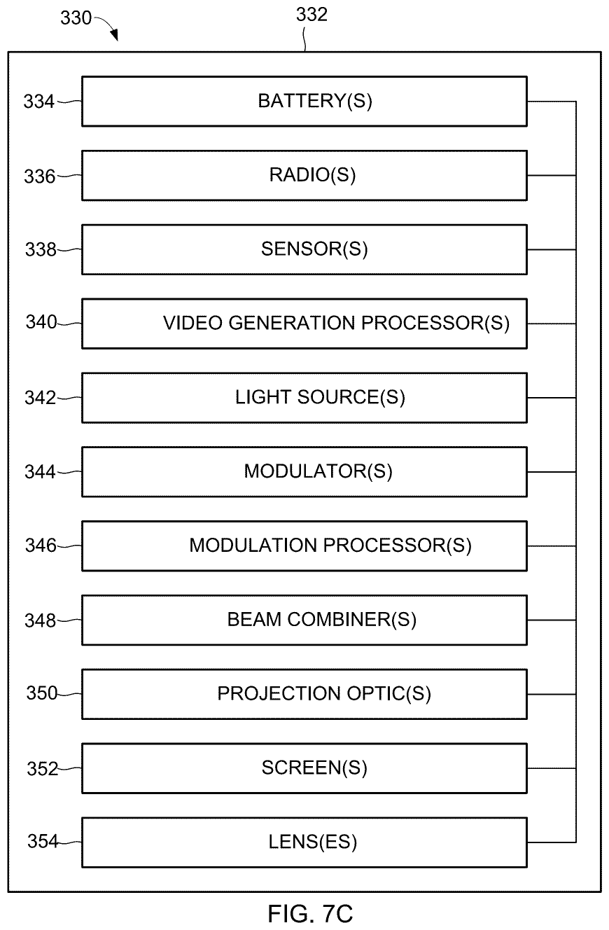

FIG. 7A schematically illustrates an example camera flash system 310 comprising an LED or pcLED array and an optical (e.g., lens) system 312, which may be or comprise an adaptive lighting system as described above in which LEDs or pcLEDs in the array may be individually operable or operable as groups. In operation of the camera flash system, illumination from some or all of the LEDs or pcLEDs in array and optical system 312 may be adjusted—deactivated, operated at full intensity, or operated at an intermediate intensity. The array may be a monolithic array, or comprise one or more monolithic arrays, as described above. The array may be a microLED array, as described above.

Flash system 310 also comprises an LED driver 316 that is controlled by a controller 314, such as a microprocessor. Controller 314 may also be coupled to a camera 317 and to sensors 318 and operate in accordance with instructions and profiles stored in memory 311. Camera 317 and LED or pcLED array and lens system 312 may be controlled by controller 314 to, for example, match the illumination provided by system 312 (i.e., the field of view of the illumination system) to the field of view of camera 317, or to otherwise adapt the illumination provided by system 312 to the scene viewed by the camera as described above. Sensors 318 may include, for example, positional sensors (e.g., a gyroscope and/or accelerometer) and/or other sensors that may be used to determine the position and orientation of system 310.

FIG. 7B schematically illustrates an example display system 320 that includes an array 321 of LEDs or pcLEDs that are individually operable or operable in groups, a display 322, a light emitting array controller 323, a sensor system 324, and a system controller 325. Array 321 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Similarly, to provide redundancy in the event of a defective LED or pcLED, a group of six individually operable adjacent LEDs or pcLEDs comprising two red emitters, two blue emitters, and two green emitters may correspond to a single color- tunable pixel in the display Array 321 can be used to project light in graphical or object patterns that can for example support AR/VR/MR systems. In some cases the individual emitters can be referred to as pixels even if several are operated together to act as a single pixel of a display.

Sensor input is provided to the sensor system 324, while power and user data input is provided to the system controller 325. In some embodiments modules included in system 320 can be compactly arranged in a single structure, or one or more elements can be separately mounted and connected via wireless or wired communication. For example, array 321, display 322, and sensor system 324 can be mounted on a headset or glasses, with the light emitting array controller and/or system controller 325 separately mounted.

System 320 can incorporate a wide range of optics (not shown) to couple light emitted by array 321 into display 322. Any suitable optics may be used for this purpose.

Sensor system 324 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input through the sensor system can include detected touch or taps, gestural input, or control based on headset or display position.

In response to data from sensor system 324, system controller 325 can send images or instructions to the light emitting array controller 323. Changes or modification to the images or instructions can also be made by user data input, or automated data input as needed. User data input can include but is not limited to that provided by audio instructions, haptic feedback, eye or pupil positioning, or connected keyboard, mouse, or game controller.

As noted above, AR, VR, and MR systems may be more generally referred to as examples of visualization systems. In a virtual reality system, a display can present to a user a view of scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

FIG. 7C shows a generalized block diagram of an example visualization system 330. The visualization system 330 can include a wearable housing 332, such as a headset or goggles. The housing 332 can mechanically support and house the elements detailed below. In some examples, one or more of the elements detailed below can be included in one or more additional housings that can be separate from the wearable housing 332 and couplable to the wearable housing 332 wirelessly and/or via a wired connection. For example, a separate housing can reduce the weight of wearable goggles, such as by including batteries, radios, and other elements. The housing 332 can include one or more batteries 334, which can electrically power any or all of the elements detailed below. The housing 332 can include circuitry that can electrically couple to an external power supply, such as a wall outlet, to recharge the batteries 334. The housing 332 can include one or more radios 336 to communicate wirelessly with a server or network via a suitable protocol, such as WiFi.

The visualization system 330 can include one or more sensors 338, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 338 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 338 can capture a real-time video image of the surroundings proximate a user.

The visualization system 330 can include one or more video generation processors 340. The one or more video generation processors 340 can receive, from a server and/or a storage medium, scene data that represents a three-dimensional scene, such as a set of position coordinates for objects in the scene or a depth map of the scene. The one or more video generation processors 340 can receive one or more sensor signals from the one or more sensors 338. In response to the scene data, which represents the surroundings, and at least one sensor signal, which represents the location and/or orientation of the user with respect to the surroundings, the one or more video generation processors 340 can generate at least one video signal that corresponds to a view of the scene. In some examples, the one or more video generation processors 340 can generate two video signals, one for each eye of the user, that represent a view of the scene from a point of view of the left eye and the right eye of the user, respectively. In some examples, the one or more video generation processors 340 can generate more than two video signals and combine the video signals to provide one video signal for both eyes, two video signals for the two eyes, or other combinations.

The visualization system 330 can include one or more light sources 342 that can provide light for a display of the visualization system 330. Suitable light sources 342 can include any of the LEDs, pcLEDs, LED arrays, and pcLED arrays discussed above, for example those discussed above with respect to display system 320.

The visualization system 330 can include one or more modulators 344. The modulators 344 can be implemented in one of at least two configurations.

In a first configuration, the modulators 344 can include circuitry that can modulate the light sources 342 directly. For example, the light sources 342 can include an array of light-emitting diodes, and the modulators 344 can directly modulate the electrical power, electrical voltage, and/or electrical current directed to each light-emitting diode in the array to form modulated light. The modulation can be performed in an analog manner and/or a digital manner. In some examples, the light sources 342 can include an array of red light-emitting diodes, an array of green light-emitting diodes, and an array of blue light-emitting diodes, and the modulators 344 can directly modulate the red light-emitting diodes, the green light-emitting diodes, and the blue light-emitting diodes to form the modulated light to produce a specified image.

In a second configuration, the modulators 344 can include a modulation panel, such as a liquid crystal panel. The light sources 342 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 344 can include multiple modulation panels that can modulate different colors of light. For example, the modulators 344 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 344 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 330 can include one or more modulation processors 346, which can receive a video signal, such as from the one or more video generation processors 340, and, in response, can produce an electrical modulation signal. For configurations in which the modulators 344 directly modulate the light sources 342, the electrical modulation signal can drive the light sources 344. For configurations in which the modulators 344 include a modulation panel, the electrical modulation signal can drive the modulation panel.

The visualization system 330 can include one or more beam combiners 348 (also known as beam splitters 348), which can combine light beams of different colors to form a single multi-color beam. For configurations in which the light sources 342 can include multiple light-emitting diodes of different colors, the visualization system 330 can include one or more wavelength-sensitive (e.g., dichroic) beam splitters 348 that can combine the light of different colors to form a single multi-color beam.

The visualization system 330 can direct the modulated light toward the eyes of the viewer in one of at least two configurations. In a first configuration, the visualization system 330 can function as a projector, and can include suitable projection optics 350 that can project the modulated light onto one or more screens 352. The screens 352 can be located a suitable distance from an eye of the user. The visualization system 330 can optionally include one or more lenses 354 that can locate a virtual image of a screen 352 at a suitable distance from the eye, such as a close-focus distance, such as 500 mm, 750 mm, or another suitable distance. In some examples, the visualization system 330 can include a single screen 352, such that the modulated light can be directed toward both eyes of the user. In some examples, the visualization system 330 can include two screens 352, such that the modulated light from each screen 352 can be directed toward a respective eye of the user. In some examples, the visualization system 330 can include more than two screens 352. In a second configuration, the visualization system 330 can direct the modulated light directly into one or both eyes of a viewer. For example, the projection optics 350 can form an image on a retina of an eye of the user, or an image on each retina of the two eyes of the user.

For some configurations of augmented reality systems, the visualization system 330 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

For purposes of the present disclosure and appended claims, any arrangement of a layer, surface, substrate, diode structure, or other structure “on,” “over,” or “against” another such structure shall encompass arrangements with direct contact between the two structures as well as arrangements including some intervening structure between them. Conversely, any arrangement of a layer, surface, substrate, diode structure, or other structure “directly on,” “directly over,” or “directly against” another such structure shall encompass only arrangements with direct contact between the two structures. For purposes of the present disclosure and appended claims, a layer, structure, or material described as “transparent” and “substantially transparent” shall exhibit, at the nominal operating wavelength(s), a level of optical transmission that is sufficiently high, or a level of optical loss (due to absorption, scattering, or other loss mechanism) that is sufficiently low, that the light-emitting device can function within operationally acceptable parameters (e.g., output power or luminance, conversion or extraction efficiency, or other figures-of-merit including any described herein).

As is well known, transmission of light through an interface between two media of differing refractive indices is limited by so-called Fresnel reflection. For example, transmission between a semiconductor and air (refractive indices of 3 and 1, respectively) is limited to about 75% at normal incidence. In another example, transmission between an LED ceramic phosphor wavelength converter and air (refractive indices of 1.8 and 1, respectively) is limited to about 92% at normal incidence. A suitably arranged anti-reflection (AR) coating can increase transmission through the interface. Thin-film AR coatings rely on interference between light waves reflected at multiple layer interfaces to suppress reflection and increase transmission. Such coatings can reduce unwanted reflections to near zero, but require precise control and uniformity of layer thicknesses (typically to fractions of a wavelength), and can exhibit significant spectral shifts with respect to angle-of-incidence. In some instances the spectral shifts can be mitigated by employing a complex, multilayer, broadband AR coating, but with greater expense and complexity of the AR coating. However, many LED wavelength converters do not have suitably flat surfaces to enable sufficiently precise deposition of layers to form an effective thin-film AR coating. In addition, LED wavelength converters in many instances emit over a range of wavelengths or at multiple wavelengths, and emit over a broad angular range. It would be desirable to provide an AR coating that can be applied to a rough surface, that can be effective over a wide range of wavelengths and angles, and that does not require precise, subwavelength control of layer thicknesses and so can be fabricated using simpler, cheaper manufacturing processes (including wet chemical processes).

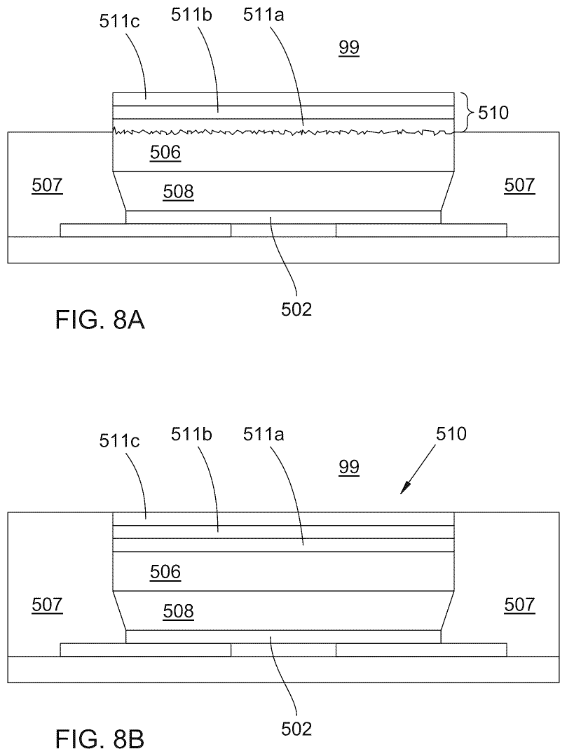

Examples of an inventive light-emitting apparatus are illustrated schematically in FIGS. 8A and 8B, which show a single light-emitting diode (LED) 502, a luminescent structure 506 (i.e., a wavelength-converting structure), and a stepped-index structure 510. The stepped-index structure 510 comprises three transparent layers 511a, 511b, and 511c in the examples shown; each can be referred to generically as the layer 511; all can be referred to collectively as the layers 511. The luminescent structure 506 comprises one or more luminescent materials (e.g., phosphors) that absorb light at an excitation wavelength and, as a result of that absorption, emit light at one or more emission wavelengths that are longer than the excitation wavelength. In some examples the luminescent structure transmits little or no light at the excitation wavelength (it is all absorbed); in some other examples the luminescent structure transmits a portion of light at the excitation wavelength. In some examples the luminescent structure 506 can emit light at a single emission wavelength (e.g., a single phosphor species emitting over a relatively narrow band of wavelengths); in some other examples the luminescent structure 506 can emit light at multiple emission wavelengths (e.g., multiple different phosphor species emitting at corresponding distinct wavelengths), or over a relatively broad continuous range of wavelengths (e.g., a phosphor species emitting over the broad wavelength range, or multiple different phosphor species emitting at corresponding wavelengths that span the broad wavelength range). In some examples the excitation or emission wavelengths can be greater than 0.2 μm, greater than 0.4 μm, greater than 0.8 μm, less than 10 μm, less than 2.5 μm, or less than 1 μm. In many examples the excitation wavelength is in the near-UV spectral region or the blue spectral region, and the emission wavelength(s) are in the visible spectral region. The luminescent structure 506 can be of any suitable type or arrangement, e.g., a layer, tile, plate, or slab, and has opposite first and second surfaces. In some examples the luminescent structure 506 can comprise a doped polycrystalline ceramic material. In some examples the luminescent structure 506 can comprise a plurality of phosphor particles in a transparent or translucent binder or matrix, e.g., a multitude of phosphor particles bound together with a transparent inorganic coating material (e.g., less than 100 nm thick deposited using atomic layer deposition (ALD)), or a plurality of phosphor particles embedded in a continuous transparent or translucent binder or matrix. In some examples combinations of different structures can be employed, e.g., a layer of coated phosphor particles on a ceramic plate.

The stepped-index structure 510 is positioned between and in contact with an ambient medium 99 (often air) and the first surface of the luminescent structure 506. The stepped-index structure 510 comprises a stack of multiple transparent layers 511, e.g., three transparent layers 511a/511b/511c in the examples shown; any suitable, desirable, or necessary number of transparent layers can be employed. Each transparent layer 511 is characterized by a corresponding effective refractive index (i.e., the refractive index of a homogeneous medium, or an averaged or weighted refractive index of a medium that is inhomogeneous only on length scales significantly smaller than the emission wavelength(s), such as a dispersion of nanoparticles). The effective refractive index of each transparent layer 511 is lower than an effective refractive index of the first surface of the luminescent structure 506 (discussed below), and is higher than a refractive index of the ambient medium 99. The corresponding effective refractive indices of the transparent layers 511 decrease monotonically among the transparent layers 511 with increasing distance of each transparent layer 511 from the first surface of the luminescent structure 506. In the examples shown, the effective refractive index of the first surface of the luminescent structure 506 is higher than the effective refractive index of the first transparent layer 511a, which is higher than the effective refractive index of the second transparent layer 511b, which is higher than the effective refractive index of the third transparent layer 511c, which is higher than the refractive index of the ambient medium 99.

The effective refractive index of the first surface of the luminescent structure 506 can depend on the type and arrangement of that structure, and typically would be determined primarily by the material of the luminescent structure 506 that is in direct contact with the first transparent layer 511a. For a doped polycrystalline ceramic material, the effective refractive index of the first surface of the luminescent structure 506 would be the refractive index of the doped ceramic material. In some examples such a ceramic material can include, e.g., doped yttrium gadolinium aluminum garnet material, doped lutetium aluminum garnet material, doped potassium fluorosilicate material, or doped strontium calcium aluminum silicon nitride material; any suitable doped ceramic material can be employed. For a plurality of phosphor particles embedded in a continuous transparent or translucent binder or matrix, the effective refractive index of the first surface of the luminescent structure 506 would be the refractive index of the binder or matrix material. Such a continuous binder or matrix can include, e.g., one or more materials among: doped or undoped silicon oxide, nitride, or oxynitride; one or more doped or undoped metal or transition metal oxides, nitrides, or oxynitrides; one or more doped or undoped semiconductor oxides, nitrides, or oxynitrides; one or more optical glasses; or one or more doped or undoped polymers. For a multitude of micron-scale phosphor particles bound together with a transparent inorganic coating material, such as a 100 nm thick coating deposited using atomic layer deposition (ALD), the effective refractive index of the first surface of the luminescent structure would be determined primarily by the refractive index of the inorganic coating material, i.e., the material of the luminescent structure 506 that is in direct contact with the first transparent layer 511a. In some examples such an inorganic coating material can include one or more metal, transition metal, or semiconductor oxides, nitrides, or oxynitrides.

The stepped-index structure 510 acts as an antireflection (AR) coating for light propagating out of the luminescent structure 506 through its first surface and into the ambient medium 99. The Fresnel reflections at four low-index-contrast interfaces (for three transparent layers 511) result in higher net transmission than that permitted by a single high-index-contrast interface. Returning to the example of a semiconductor and air (indices 3 and 1), adding a stepped-index structure having three layers of refractive indices 2.5, 2, and 1.5 increases the transmission from about 75% to about 92% (at normal incidence). In the example of a ceramic wavelength converter and air (indices 1.8 and 1), adding a stepped-index structure having three layers of refractive indices 1.6, 1.4, and 1.2 increases the transmission from 91.8% to 97.8% (at normal incidence). Those transmission levels do not vary, or vary only negligibly, with wavelength. The improvements in transmission do not depend on precise control of the thickness of any layer, and in some instances it may be desirable for thickness of the transmissive layers to be several or many times greater than the wavelength of the transmitted light to reduce or avoid unwanted interference effects. In some examples each transparent layer 511 of the stepped-index structure 510 can be greater than 0.1 μm thick, greater than 0.2 μm thick, greater than 0.3 μm thick, greater than 0.5 μm thick, greater than 0.7 μm thick, greater than 1 μm thick, greater than 2 μm thick, greater than 3 μm thick, or greater than 5 μm thick.

In some examples of an inventive light-emitting apparatus, the effective refractive index of the luminescent structure 506 can be greater than 1.7; in some examples, the refractive index of the ambient medium 99 can be about 1. In some examples the stepped-index structure 510 can comprise three transparent layers 511 having corresponding effective refractive indices between 1.6 and 1.8 for the transparent layer 511a, between 1.3 and 1.7 for the transparent layer 511b, and between 1 and 1.4 for the transparent layer 511c. In some of those examples the arrangement of the stepped-index structure 510 can result in average transmission over the visible spectrum, from the luminescent structure 506 into the ambient medium 99, that is greater than 95% at normal incidence, or greater than 97% at normal incidence. In some of those examples the arrangement of the stepped-index structure 510 can result in average transmission over the visible spectrum, from the luminescent structure 506 into the ambient medium 99, that is greater than 93%, or greater than 96%, averaged over incidence angles below an angle of total internal reflection.

In some examples one or more of the transparent layers 511 can be formed by one or more among chemical vapor deposition processes, atomic layer deposition processes, or epitaxial growth or deposition processes. In some examples some or all of the layers 511 can be formed using one or more of those processes.

In some examples the first transparent layer 511a of the stepped-index structure can comprise a solidified material derived from one or more liquid precursors applied to the first surface of the luminescent structure 506. In some examples at least one of the other transparent layers 511b/511c/etc of the stepped-index structure 510 can comprise a corresponding solidified material derived from one or more liquid precursors applied to an adjacent transparent layer 511 of the stepped-index structure 510. In some examples some or all of the layers 511 can be formed in this way.

Because the transparent layers 511 can be thick, and need not have precisely controlled thickness, the stepped-index structure 510 can be advantageously employed for increasing transmission through a rough first surface of the luminescent structure 506 (schematically represented in FIG. 8A). In some examples polycrystalline ceramic material often exhibits cracks, fissures, or other non-planar surface topography. In some examples some phosphor particles in a continuous binder or matrix can partly protrude from the binder or matrix to create non-planar surface topography. In some examples phosphor particles bound together by a thin ALD coating form non-planar surface topography. In some examples of those cases, material of the first transparent layer 511a positioned against the first surface of the luminescent structure 506 can at least partly fill in non-planar surface topography of that first surface. Such an arrangement can be achieved, e.g., by applying material of the first layer 511a to the first surface of the luminescent structure 506 as a liquid precursor that is subsequently solidified (discussed further below). The liquid precursor can flow and at least partly fill in the non-planar surface topography of the first surface of the luminescent structure 506 before solidification.

In some examples (e.g., as in FIG. 8A) the first surface of the luminescent structure 506 can be characterized by a first surface roughness, and the opposite surface of the first transparent layer 511a (that forms an interface with the second transparent layer 511b) can be characterized by a second surface roughness that is less than the first surface roughness. Such an arrangement can be achieved in some examples by applying a liquid precursor to the first surface of the luminescent structure 506. Before solidifying, the upper surface of the liquid precursor can assume a nearly planar shape, e.g., by spin coating or other suitable application technique. Such an arrangement can be achieved in other examples by first depositing, growing, forming, or applying the solid material of the transparent layer 511a in any suitable way that at least partly fills in the non-planar topography of the first surface of the luminescent structure 506, and then planarizing that material to form a flat surface on which to form the next transparent layer 511b. The planarization can be achieved in any suitable way, e.g., grinding, lapping, polishing, chemical-mechanical planarization (CMP), and so forth.

In some examples one or more homogeneous materials can be chosen for forming the transparent layers 511 that exhibit the desired refractive indices. Suitable materials can include one or more materials among: doped or undoped silicon oxide, nitride, or oxynitride; one or more doped or undoped metal or transition metal oxides, nitrides, or oxynitrides; one or more doped or undoped semiconductor oxides, nitrides, or oxynitrides; one or more optical glasses; or one or more doped or undoped polymers.

In many instances, however, materials that exhibit the desired refractive indices and that are also physically and chemically suited for forming the transparent layers 511 might not be available, or might not even exist. In such cases one or more of the layers 511 can comprise a corresponding host material and a plurality of particles or inclusions embedded in the host material. The particles or inclusions are significantly smaller than any emission wavelength of the luminescent structure 506, i.e., small enough to result in no or only negligible scattering of light at those wavelengths (e.g., less than a quarter of the wavelength, less than a tenth of the wavelength, or less than 100 nm). In other words, the particles or inclusions are small enough that the corresponding transparent layer 511 acts like a homogeneous medium with respect to the light emitted by the luminescent structure 506, even though that transparent layer 511 is inhomogeneous on subwavelength scales.

In some examples in which a transparent layer 511 comprises particles or inclusions in a host material, the number density of the particles or inclusions can be sufficiently large, and the refractive index of the particles or inclusions can be sufficiently high, so that the corresponding transparent layer 511 of the stepped-index structure 510 exhibits an effective refractive index that is higher than the refractive index of the host material. For a given combination of host material and particle/inclusion material, the number density of the particles or inclusions can be chosen to result in a desired effective refractive index for that layer 511. In some examples the particles or inclusions can comprise one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped metal or transition metal oxides, nitrides, or oxynitrides; one or more doped or undoped semiconductor oxides, nitrides, or oxynitrides; one or more optical glasses; or one or more doped or undoped polymers. In some examples the particles or inclusions can comprise titania or zirconia nanoparticles. In some examples the host material can include one or more materials among: doped or undoped silicon oxide, nitride, or oxynitride; one or more doped or undoped metal or transition metal oxides, nitrides, or oxynitrides; one or more doped or undoped semiconductor oxides, nitrides, or oxynitrides; one or more optical glasses; or one or more doped or undoped polymers.

In some other examples in which a transparent layer 511 comprises particles or inclusions in a host material, the number density of the particles or inclusions can be sufficiently large, and the refractive index of the particles or inclusions can be sufficiently low, so that the corresponding transparent layer 511 of the stepped-index structure 510 exhibits an effective refractive index that is lower than the refractive index of the host material. For a given combination of host material and particle/inclusion material, the number density of the particles or inclusions can be chosen to result in a desired effective refractive index for that layer 511. In some examples the particles or inclusions can comprise one or more materials among: doped or undoped silicon oxide, nitride, or oxynitride; one or more doped or undoped metal or transition metal oxides, nitrides, or oxynitrides; one or more doped or undoped semiconductor oxides, nitrides, or oxynitrides; one or more optical glasses; or one or more doped or undoped polymers. In some examples the particles or inclusions can comprise voids or pockets in the host material. In some examples the host material can include one or more materials among those listed above.

Some examples of a stepped-index structure 510 can include multiple transparent layers 511 that each comprise a corresponding host material and corresponding particles or inclusions. Those transparent layers 511 can differ from one another with respect to type or composition of the host material, the type, size, or composition of the particles or inclusions, number density of the particles or inclusions, or the effective refractive index (either higher or lower than that of the corresponding host material).

In some examples in which a transparent layer 511 comprises particles or inclusions in a host material, one or more of the transparent layers 511 can be formed by applying one or more liquid precursors and curing the precursors to solidify the corresponding transparent layer. The one or more liquid precursors can include a plurality of particles or inclusions dispersed therein, which remain embedded in the corresponding transparent layer 511 after curing.

In some examples in which a transparent layer 511 comprises voids or pockets in a host material, one or more of the transparent layers 511 can be formed by applying one or more liquid precursors and curing the precursors to solidify the corresponding transparent layer. The one or more liquid precursors can include a plurality of organic particles or inclusions dispersed therein, which are pyrolyzed during curing so as to leave a plurality of voids or pockets in the corresponding transparent layer 511 after curing.

In any example in which one or more liquid precursors are applied, one or more of those precursors can be applied by inkjet printing, spin coating, dip coating, one or more wet chemical processes, or any other suitable dispensing or application process.

The LED 502 is positioned with its light-emitting surface thereof facing the second surface of the luminescent structure 506. Light at the excitation wavelength is emitted by the LED 502, exits the light-emitting surface thereof, and enters the luminescent structure 506 through its second surface. At least a portion of the light emitted by the LED 502 is absorbed by the luminescent structure 506 and converted to light at the emission wavelength(s), at least a portion of which exits the luminescent structure 506 through its first surface and through the stepped-index structure 510. The LED 502 can include one or more materials among doped or undoped III-V, II-VI, or Group IV semiconductor materials or alloys or mixtures thereof.

In some examples (e.g., as in FIGS. 8A and 8B9), a transparent substrate 508 is positioned between the light-emitting surface of the LED 502 and the second surface of the luminescent structure 506. In some examples the substrate 508 is the substrate on which the LED 502 was fabricated. In some examples the substrate can comprise sapphire; any suitable transparent material can be employed.

Each of the examples of FIGS. 8A and 8B includes an optical side coating 507 positioned against lateral surfaces of the LED 502 and the transparent substrate 508. The optical side coating 507 can be structurally arranged so as to reflect or scatter light at the emission wavelength(s) and, in some instances, the excitation wavelength as well. In the example of FIG. 8 the optical side coating 507 stops at the first surface of the luminescent structure 506. In the example of FIG. 8B the optical side coating 507 extends beyond the first surface of the luminescent structure 506 and onto lateral surfaces of the stepped-index structure 510. In both arrangements the optical side coating 507 can redirect at least some of the light that would otherwise have exited the side of the light-emitting apparatus to instead exit through the first surface of the luminescent structure 506 and through the stepped-index structure 510.

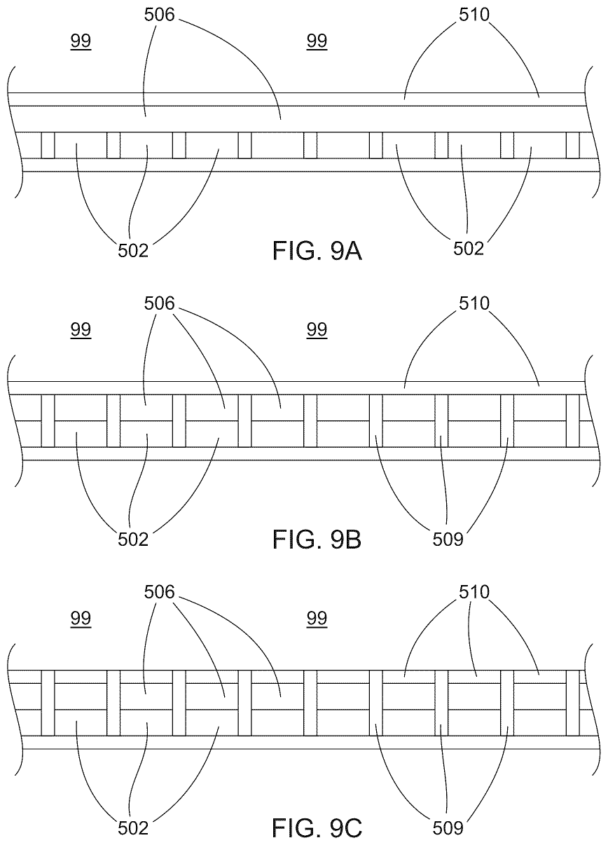

In some examples (e.g., including those of FIGS. 8A and 8B) the light-emitting apparatus includes only a single LED 502. In other examples (e.g., including those of FIGS. 9A-9C) the light-emitting apparatus includes an array of multiple LEDs 502. In some examples the array can include multiple discrete, structurally distinct LEDs 502 assembled together to form the array; in some examples the array can include multiple LEDs 502 integrally formed together on a common device substrate. In some examples the array can include multiple microLEDs, with nonzero spacing of the microLEDs of the array being less than 200 μm or even smaller (as described above), or nonzero separation between adjacent microLEDs of the array being less than 50 μm or even smaller (as described above). “Nonzero” spacing indicates spacing that, no matter how small, still permits the individual LEDs to function as LEDs; “nonzero” separation indicates separation that, no matter how small, still permits adjacent LEDs to operate independently.

In some examples (e.g., as in FIG. 9A) the luminescent structure 506 and the stepped-index structure 510 span multiple LEDs 502 of the array. In some examples (e.g., as in FIG. 9B) the luminescent structure 506 can comprise multiple discrete areal segments, with each areal segment aligned with a corresponding LED 502 of the array. In some such examples, lateral light barriers 509 can be positioned between adjacent LEDs 502 of the array and can extend between adjacent areal segments of the luminescent structure 506.

In some examples (e.g., as in FIG. 9C) both the luminescent structure 506 and the stepped-index structure 510 can comprise multiple discrete areal segments; each areal segment of the luminescent structure can be aligned with a corresponding LED 502, and each areal segment of the stepped-index structure 510 can be aligned with a corresponding areal segment of the luminescent structure 506. In some such examples the lateral light barriers 509 can be positioned between adjacent LEDs 502 and can extend between adjacent areal segments of the luminescent structure 506 and between adjacent areal segments of the stepped-index structure 510.

In addition to the preceding, the following example embodiments fall within the scope of the present disclosure or appended claims. Any given Example below that refers to some or all preceding Examples shall be understood to refer to only those preceding Examples with which the given Example is not inconsistent, and to exclude those preceding Examples with which the given Example is inconsistent.

Example 1. A light-emitting apparatus comprising: (a) a luminescent structure comprising one or more luminescent materials that absorb light at an excitation wavelength and, as a result of that absorption, emit light at one or more emission wavelengths that are longer than the excitation wavelength, said luminescent structure having opposite first and second surfaces thereof; and (b) a stepped-index structure comprising a stack of multiple transparent layers, each transparent layer being characterized by a corresponding effective refractive index that is lower than an effective refractive index of the first surface of the luminescent structure and higher than a refractive index of an ambient medium, the stepped-index structure being positioned between and in contact with the ambient medium and the first surface of the luminescent structure, the corresponding effective refractive indices of the transparent layers decreasing monotonically among the transparent layers with increasing distance of each transparent layer from the first surface of the luminescent structure.

Example 2. The light-emitting apparatus of Example 1 further comprising one or more light-emitting diodes (LEDs) positioned with corresponding light-emitting surfaces thereof facing the second surface of the luminescent structure.

Example 3. The light-emitting apparatus of Example 2, the one or more LEDs including one or more materials among doped or undoped III-V, II-VI, or Group IV semiconductor materials or alloys or mixtures thereof.

Example 4. The light-emitting apparatus of any one of Examples 2 or 3 further comprising a transparent substrate between the one or more LEDs and the second surface of the luminescent structure.

Example 5. The light-emitting apparatus of Example 4 further comprising an optical side coating positioned against lateral surfaces of the one or more LEDs and the transparent substrate, the optical side coating being structurally arranged so as to reflect or scatter light at the one or more emission wavelengths.

Example 6. The light-emitting apparatus of Example 5, the optical side coating extending beyond the first surface of the luminescent structure and onto lateral surfaces of the stepped-index structure.

Example 7. The light-emitting apparatus of any one of Examples 2 through 6, light-emitting apparatus including only a single LED.

Example 8. The light-emitting apparatus of any one of Examples 2 through 6, the one or more LEDs comprising an array of multiple LEDs.

Example 9. The light-emitting apparatus of Example 8, the array comprising multiple microLEDs, nonzero spacing of the microLEDs of the array being less than 200 μm, or nonzero separation between adjacent microLEDs of the array being less than 50 μm.

Example 10. The light-emitting apparatus of any one of Examples 8 or 9, the luminescent structure and the stepped-index structure spanning multiple LEDs of the array.

Example 11. The light-emitting apparatus of any one of Examples 8 or 9, the luminescent structure comprising multiple discrete areal segments thereof, with each areal segment being aligned with a corresponding LED of the array.

Example 12. The light-emitting apparatus of Example 11 further comprising lateral light barriers positioned between adjacent LEDs of the array and extending between adjacent areal segments of the luminescent structure.

Example 13. The light-emitting apparatus of any one of Examples 11 or 12, the stepped-index structure comprising multiple discrete areal segments thereof, with each areal segment of the stepped-index structure being aligned with a corresponding areal segment of the luminescent structure.

Example 14. The light-emitting apparatus of Example 13 further comprising lateral light barriers positioned between adjacent LEDs of the array and extending between adjacent areal segments of the luminescent structure and between adjacent areal segments of the stepped-index structure.

Example 15. The light-emitting apparatus of any one of Examples 1 through 14, wherein (i) the first surface of the luminescent structure is characterized by a first surface roughness, and (ii) an interface between the transparent layer of the stepped-index structure positioned against the first surface of the luminescent structure and an immediately adjacent transparent layer of the stepped-index structure is characterized by a second surface roughness that is less than the first surface roughness.

Example 16. The light-emitting apparatus of any one of Examples 1 through 15, material of the transparent layer of the stepped-index structure positioned against the first surface of the luminescent structure at least partly filling in non-planar surface topography of the first surface of the luminescent structure.

Example 17. The light-emitting apparatus of any one of Examples 1 through 16, at least one transparent layer of the stepped-index structure comprising a corresponding host material and a plurality of particles or inclusions embedded in the host material, the particles or inclusions being sufficiently smaller than any emission wavelength of the luminescent structure so as to result in no or only negligible scattering of light at the one or more emission wavelengths.

Example 18. The light-emitting apparatus of Example 17, number density of the particles or inclusions being sufficiently large and a refractive index of the particles or inclusions being sufficiently high so that the corresponding transparent layer of the stepped-index structure exhibits an effective refractive index that is higher than a refractive index that characterizes the host material.

Example 19. The light-emitting apparatus of Example 18, the particles or inclusions comprising one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped metal or transition metal oxides, nitrides, or oxynitrides; one or more doped or undoped semiconductor oxides, nitrides, or oxynitrides; one or more optical glasses; or one or more doped or undoped polymers.

Example 20. The light-emitting apparatus of Example 18, the particles or inclusions comprising titania or zirconia nanoparticles.

Example 21. The light-emitting apparatus of any one of Examples 1 through 16, number density of the particles or inclusions being sufficiently large and a refractive index of the particles or inclusions being sufficiently low so that the corresponding transparent layer of the stepped-index structure exhibits an effective refractive index that is lower than a refractive index that characterizes the host material.

Example 22. The light-emitting apparatus of Example 21, the particles or inclusions comprising one or more materials among: doped or undoped silicon oxide, nitride, or oxynitride; one or more doped or undoped metal or transition metal oxides, nitrides, or oxynitrides; one or more doped or undoped semiconductor oxides, nitrides, or oxynitrides; one or more optical glasses; or one or more doped or undoped polymers.

Example 23. The light-emitting apparatus of Example 21, the particles or inclusions comprising voids or pockets in the host material.

Example 24. The light-emitting apparatus of any one of Examples 16 through 24, the host material including one or more materials among: doped or undoped silicon oxide, nitride, or oxynitride; one or more doped or undoped metal or transition metal oxides, nitrides, or oxynitrides; one or more doped or undoped semiconductor oxides, nitrides, or oxynitrides; one or more optical glasses; or one or more doped or undoped polymers.

Example 25. The light-emitting apparatus of any preceding claim, including (i) at least one transparent layer arranged according to any one of Examples 18, 19, 20, or 24, and (ii) at least one transparent layer arranged according to any one of Examples 21, 22, 23, or 24.

Example 26. The light-emitting apparatus of any one of Examples 1 through 25, one or more transparent layers of the stepped-index structure including one or more materials among: doped or undoped silicon oxide, nitride, or oxynitride; one or more doped or undoped metal or transition metal oxides, nitrides, or oxynitrides; one or more doped or undoped semiconductor oxides, nitrides, or oxynitrides; one or more optical glasses; or one or more doped or undoped polymers.

Example 27. The light-emitting apparatus of any one of Examples 1 through 26, at least one transparent layer of the stepped-index structure comprising a solidified material derived from one or more liquid precursors applied to the first surface of the luminescent structure.

Example 28. The light-emitting apparatus of any one of Examples 1 through 27, at least one transparent layer of the stepped-index structure comprising a solidified material derived from one or more liquid precursors applied to an adjacent transparent layer of the stepped-index structure.

Example 29. The light-emitting apparatus of any one of Examples 1 through 28, the effective refractive index of the luminescent structure being greater than 1.7, the refractive index of the ambient medium being 1, and the stepped-index structure comprising three transparent layers having corresponding effective refractive indices between 1.6 and 1.8, between 1.3 and 1.7, and between 1 and 1.4, respectively.

Example 30. The light-emitting apparatus of Example 29, the arrangement of the stepped-index structure resulting in average transmission over the visible spectrum from the luminescent structure into the ambient medium that is greater than 95% at normal incidence, or greater than 97% at normal incidence.

Example 31. The light-emitting apparatus of any one of Examples 29 or 30, the arrangement of the stepped-index structure resulting in average transmission over the visible spectrum from the luminescent structure into the ambient medium that is greater than 93%, or greater than 96%, averaged over incidence angles below an angle of total internal reflection.

Example 32. The light-emitting apparatus of any one of Examples 1 through 31, each transparent layer of the stepped-index structure being greater than 0.1 μm thick, greater than 0.2 μm thick, greater than 0.3 μm thick, greater than 0.5 μm thick, greater than 0.7 μm thick, greater than 1 μm thick, greater than 2 μm thick, greater than 3 μm thick, or greater than 5 μm thick.

Example 33. The light-emitting apparatus of any one of Examples 1 through 32, the luminescent structure comprising a doped polycrystalline ceramic material.

Example 34. The light-emitting apparatus of any one of Examples 1 through 33, the luminescent structure comprising a multitude of phosphor particles bound together with a transparent inorganic coating material.

Example 35. The light-emitting apparatus of any one of Examples 1 through 34, each luminescent structure comprising a plurality of phosphor particles embedded in a continuous transparent or translucent binder or matrix.

Example 36. A method for making the light-emitting apparatus of any one of any one of Examples 1 through 35, the method comprising: (A) forming a first transparent layer on a first surface of a luminescent structure, the luminescent structure comprising one or more luminescent materials that absorb light at an excitation wavelength and, as a result of that absorption, emit light at one or more emission wavelengths that are longer than the excitation wavelength, said luminescent structure having opposite first and second surfaces thereof, the first transparent layer having an effective refractive index lower than an effective refractive index of the first surface of the luminescent structure; and (B) forming on the first transparent layer a stack of one or more additional transparent layers to form a stepped-index structure, each additional transparent layer being characterized by a corresponding effective refractive index that is lower than an effective refractive index of the first transparent layer and higher than a refractive index of an ambient medium, the stepped-index structure being positioned between and in contact with the ambient medium and the first surface of the luminescent structure, the corresponding effective refractive indices of the transparent layers decreasing monotonically among the first and additional transparent layers with increasing distance of each transparent layer from the first surface of the luminescent structure.

Example 37. The method of Example 36, one or more of the transparent layers being formed by applying one or more liquid precursors and curing the precursors to solidify the corresponding transparent layer.

Example 38. The method of Example 37, the one or more liquid precursors including a plurality of particles or inclusions dispersed therein, the particles or inclusions remaining embedded in the corresponding transparent layer after curing.

Example 39. The method of Example 37, the one or more liquid precursors including a plurality of organic particles or inclusions dispersed therein, the organic particles or inclusions being pyrolyzed during curing so as to leave a plurality of voids or pockets in the corresponding transparent layer after curing.

Example 40. The method of any one of Examples 37 through 39, the one or more liquid precursors being applied by inkjet printing, spin coating, dip coating, or one or more wet chemical processes.

Example 41. The method of any one of Examples 36 through 40, one or more of the transparent layers being formed by one or more among chemical vapor deposition processes, atomic layer deposition processes, or epitaxial growth or deposition processes.

Example 42. The method of any one of Examples 36 through 41, the first transparent layer being formed by applying one or more liquid precursors to the first surface of the luminescent structure to at least partly fill in non-planar surface topography of the first surface of the luminescent structure and to form a flat surface of the first transparent layer facing away from the luminescent structure, and curing the precursors to solidify the first transparent layer.

Example 43. The method of any one of Examples 36 through 41, the first transparent layer at least partly filling in non-planar surface topography of the first surface of the luminescent structure, the method further comprising planarizing the first transparent layer to form a flat surface of the first transparent layer facing away from the luminescent structure, the stack of one or more additional transparent layers being formed on the planarized first transparent layer.

This disclosure is illustrative and not limiting. Further modifications will be apparent to one skilled in the art in light of this disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of any single disclosed example embodiment. Therefore, the present disclosure shall be construed as implicitly disclosing any embodiment having any suitable subset of one or more features—which features are shown, described, or claimed in the present application—including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open-ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth. For null quantities described by phrases such as “prevented,” “absent,” “eliminated,” “equal to zero,” “negligible,” and so forth (with or without terms such as “substantially” or “about”), each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled.

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC § 112 (f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112(f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A light-emitting apparatus comprising:
a luminescent structure comprising one or more luminescent materials that absorb light at an excitation wavelength and, as a result of that absorption, emit light at one or more emission wavelengths that are longer than the excitation wavelength, said luminescent structure having opposite first and second surfaces thereof; and
a stepped-index structure comprising a stack of multiple transparent layers, each transparent layer being characterized by a corresponding effective refractive index that is lower than an effective refractive index of the first surface of the luminescent structure and higher than a refractive index of an ambient medium, the stepped-index structure being positioned between and in contact with the ambient medium and the first surface of the luminescent structure, the corresponding effective refractive indices of the transparent layers decreasing monotonically among the transparent layers with increasing distance of each transparent layer from the first surface of the luminescent structure.

2. The light-emitting apparatus of claim 1 further comprising one or more light-emitting diodes (LEDs) positioned with corresponding light-emitting surfaces thereof facing the second surface of the luminescent structure.

3. The light-emitting apparatus of claim 1 wherein (i) the first surface of the luminescent structure is characterized by a first surface roughness, and (ii) an interface between the transparent layer of the stepped-index structure positioned against the first surface of the luminescent structure and an immediately adjacent transparent layer of the stepped-index structure is characterized by a second surface roughness that is less than the first surface roughness.

4. The light-emitting apparatus of claim 1, material of the transparent layer of the stepped-index structure positioned against the first surface of the luminescent structure at least partly filling in non-planar surface topography of the first surface of the luminescent structure.

5. The light-emitting apparatus of claim 1, at least one transparent layer of the stepped-index structure comprising a corresponding host material and a plurality of particles or inclusions embedded in the host material, the particles or inclusions being sufficiently smaller than any emission wavelength of the luminescent structure so as to result in no or only negligible scattering of light at the one or more emission wavelengths.

6. The light-emitting apparatus of claim 5 wherein (i) number density of the particles or inclusions of at least one of the transparent layers is sufficiently large and a refractive index of the particles or inclusions in that transparent layer is sufficiently high so that that transparent layer of the stepped-index structure exhibits an effective refractive index that is higher than a refractive index that characterizes the corresponding host material of that transparent layer, or (ii) number density of the particles or inclusions of at least one of the transparent layers is sufficiently large and a refractive index of the particles or inclusions in that transparent layer is sufficiently low so that that transparent layer of the stepped-index structure exhibits an effective refractive index that is lower than a refractive index that characterizes the corresponding host material of that transparent layer.

7. The light-emitting apparatus of claim 6 wherein the particles or inclusions of at least one of the transparent layers include titania or zirconia nanoparticles.

8. The light-emitting apparatus of claim 6 wherein the particles or inclusions of at least one of the transparent layers include voids or pockets in the corresponding host material.

9. The light-emitting apparatus of claim 1, at least one transparent layer of the stepped-index structure comprising a solidified material derived from one or more liquid precursors applied to the first surface of the luminescent structure.

10. The light-emitting apparatus of claim 1, at least one transparent layer of the stepped-index structure comprising a solidified material derived from one or more liquid precursors applied to an adjacent transparent layer of the stepped-index structure.

11. The light-emitting apparatus of claim 1, the effective refractive index of the luminescent structure being greater than 1.7, the refractive index of the ambient medium being 1, and the stepped-index structure comprising three transparent layers having corresponding effective refractive indices between 1.6 and 1.8, between 1.3 and 1.7, and between 1 and 1.4, respectively.

12. The light-emitting apparatus of claim 11, the arrangement of the stepped-index structure resulting in average transmission over the visible spectrum from the luminescent structure into the ambient medium that is (i) greater than 95% at normal incidence, or (ii) greater than 93%, averaged over incidence angles below an angle of total internal reflection.

13. The light-emitting apparatus of claim 1, each transparent layer of the stepped-index structure being greater than 0.1 μm thick.

14. The light-emitting apparatus of claim 1, the luminescent structure comprising (i) a doped polycrystalline ceramic material, (ii) a multitude of phosphor particles bound together with a transparent inorganic coating material, or (iii) a plurality of phosphor particles embedded in a continuous transparent or translucent binder or matrix.

15. A method for making the light-emitting apparatus, the method comprising:
forming a first transparent layer on a first surface of a luminescent structure, the luminescent structure comprising one or more luminescent materials that absorb light at an excitation wavelength and, as a result of that absorption, emit light at one or more emission wavelengths that are longer than the excitation wavelength, said luminescent structure having opposite first and second surfaces thereof, the first transparent layer having an effective refractive index lower than an effective refractive index of the first surface of the luminescent structure; and
forming on the first transparent layer a stack of one or more additional transparent layers to form a stepped-index structure, each additional transparent layer being characterized by a corresponding effective refractive index that is lower than an effective refractive index of the first transparent layer and higher than a refractive index of an ambient medium, the stepped-index structure being positioned between and in contact with the ambient medium and the first surface of the luminescent structure, the corresponding effective refractive indices of the transparent layers decreasing monotonically among the first and additional transparent layers with increasing distance of each transparent layer from the first surface of the luminescent structure.

16. The method of claim 15, one or more of the transparent layers being formed by applying one or more liquid precursors and curing the precursors to solidify the corresponding transparent layer.

17. The method of claim 16 wherein (i) for at least one of the transparent layers, the one or more liquid precursors include a plurality of particles or inclusions dispersed therein, the particles or inclusions remaining embedded in the corresponding transparent layer after curing, or (ii) for at least one of the transparent layers, the one or more liquid precursors include a plurality of organic particles or inclusions dispersed therein, the organic particles or inclusions being pyrolyzed during curing so as to leave a plurality of voids or pockets in the corresponding transparent layer after curing.

18. The method of claim 15, one or more of the transparent layers being formed by one or more among chemical vapor deposition processes, atomic layer deposition processes, or epitaxial growth or deposition processes.

19. The method of claim 15, the first transparent layer being formed by applying one or more liquid precursors to the first surface of the luminescent structure to at least partly fill in non-planar surface topography of the first surface of the luminescent structure and to form a flat surface of the first transparent layer facing away from the luminescent structure, and curing the precursors to solidify the first transparent layer.

20. The method of claim 15, the first transparent layer at least partly filling in non-planar surface topography of the first surface of the luminescent structure, the method further comprising planarizing the first transparent layer to form a flat surface of the first transparent layer facing away from the luminescent structure, the stack of one or more additional transparent layers being formed on the planarized first transparent layer.
